(19) United States
(12) Patent Application Publication
(10) Pub. No.: US 2025/0273525 A1
(43) Pub. Date: Aug. 28, 2025

(54) SAWN INDIVIDUALLY MOLDED QUAD FLAT NO-LEAD (QFN) SEMICONDUCTOR PACKAGE

(71) Applicant: Texas Instruments Incorporated, Dallas, TX (US)

(72) Inventors: Ruben Rolda, Plano, TX (US); Robert Mortan, McKinney, TX (US)

(21) Appl. No.: 18/589,854

(22) Filed: Feb. 28, 2024

(51) Int. Cl. H01L 23/31; H01L 21/56; H01L 23/00; H01L 23/495

(52) U.S. Cl. CPC H01L 23/3107; H01L 21/561; H01L 21/565; H01L 23/4951; H01L 23/49513; H01L 24/16; H01L 24/48; H01L 24/49; H01L 24/32; H01L 24/73; H01L 2224/16245; H01L 2224/32245; H01L 2224/48091; H01L 2224/48245; H01L 2224/49173; H01L 2224/73265

(57) ABSTRACT

A semiconductor package may have a microelectronic component electrically coupled to a plurality of leads which extend to a perimeter of the semiconductor package. A mold compound, which is electrically insulating, contacts the plurality of leads and the microelectronic component. Mold Array Process (MAP) molded Quad Flat No-Lead (QFN) packaging may apply mold compound to multiple microelectronic components simultaneously. After molding, the packages are cured and singulated. A mold compound middle mold chase with a mold cavity for each package and a mold compound injection port associated with each semiconductor package to distribute the mold compound may decreases micro voiding of the mold compound, raise the coefficient of thermal expansion, and improve board level reliability. Semiconductor packages formed with a mold compound injection port corresponding to each package may have a gate cull on the exterior of the semiconductor package where the mold compound enters the mold cavity.

### TECHNICAL FIELD

This disclosure relates to the field of semiconductor packages. More particularly, but not exclusively, this disclosure relates to quad flat no-lead semiconductor packages.

### BACKGROUND

Quad flat no-lead (QFN) packages have emerged as a popular choice for compact and high-performance microelectronic component packaging. QFN packages have metal pads on the bottom surface of the package, enabling a higher pin density in a smaller form factor. QFN packages exhibit shorter electrical paths, leading to lower inductance, reduced parasitic capacitance, and enhanced high-frequency performance. QFN packages offer simplified assembly processes, increased automation compatibility, and reduced material costs.

### SUMMARY

A semiconductor package may have a plurality of leads around a perimeter of the semiconductor package and a microelectronic component electrically coupled to the plurality of the leads. The plurality of leads may be part of a lead frame. A mold compound, which is electrically insulating, contacts the leads and the microelectronic component. Mold Array Process (MAP) molded Quad Flat No-Lead (QFN) packaging may apply mold compound to multiple microelectronic components and their associated leads simultaneously in one large, common mold cavity. After molding, the semiconductor packages are then cured and singulated by a sawing method. Semiconductor packages formed by MAP molded QFN packages may have a lower coefficient of thermal expansion and a wider variation of coefficient of thermal expansion than punched individually molded single die QFN packages formed using the same mold compound. A lower coefficient of thermal expansion and a wider variation of coefficient of thermal expansion may result in degraded solder joint and board level reliability for the MAP molded QFN packages. The difference in coefficient of thermal expansion may be due to higher levels of micro voiding in the mold compound during polymerization of the mold compound during a mold compound curing process. A mold compound middle mold chase with a mold cavity for each semiconductor package and a mold compound injection port associated with each semiconductor package may decrease micro voiding, yielding mechanical properties similar to the mold compound physical bulk properties which may improve solder joint and board level reliability. A mold compound injection port over the center point of the mold cavity may minimize wire sweep. Semiconductor packages formed with a mold compound injection port associated with each semiconductor package may have a gate cull mark on the exterior of the semiconductor package at the site where the mold compound enters the mold cavity.

### BRIEF DESCRIPTION OF THE FIGURES

FIG. 1A is a top-down view of an example semiconductor package with a semiconductor component on a semiconductor package lead frame.

FIG. 1B is a perspective view of an example semiconductor package upper mold chase and middle mold chase. The middle mold chase includes mold cavities and a mold compound injection port for each package of the middle mold chase.

FIGS. 1C-1F are cross sections of an example semiconductor package in various states of formation.

FIGS. 2A-2E are cross sections of an example semiconductor package in various states of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values. Microelectronic devices are being continually improved to reliably operate with higher performance and smaller feature sizes.

A semiconductor package contains a microelectronic component electrically coupled to a plurality of leads around a perimeter of the semiconductor package. The plurality of leads may be attached to a lead frame. The lead frame contains a plurality of semiconductor packages. A mold compound, which is electrically insulating, is formed on the plurality of leads and the microelectronic component. The mold compound is formed between a bottom mold chase and a middle mold chase. A top mold chase is on the middle mold chase. It is advantageous for the middle mold chase to have a series of middle mold chase ridges which form a portion of a mold cavity surrounding each microelectronic component to be packaged and for each mold cavity to have a mold compound injection port to deliver the mold compound to each mold cavity, the mold compound being distributed to each mold compound injection port by mold compound runners within the top mold chase. The ability to deliver mold compound to each individual semiconductor package is advantageous as it may minimize micro voiding of the mold compound which may lead to a lower coefficient of thermal expansion which may lead to solder bond and board level reliability degradation compared to a semiconductor package formed with a middle mold chase without middle mold chase ridges and/or a mold compound injection port for each semiconductor package. After the formation of the mold compound, the middle mold chase and the bottom mold chase are removed. When the middle mold chase is removed, a gate cull mark is left on the semiconductor package where the mold compound detaches from the top mold compound injection port.

After the formation of the semiconductor package on the lead frame, individual semiconductor packages may be singulated by sawing through the leads. The sidewalls of the singulated packages may be vertical with respect to the top surface of the semiconductor package if the semiconductor package is sawn between the microelectronic component and a mold compound depression formed by the middle mold chase ridges between semiconductor packages. A tapered sidewall profile may result if the singulation sawing process is along the mold compound depression. Singulation by sawing enables forming a plurality of semiconductor packages concurrently using the lead frame, as the mold compound can be formed on all the semiconductor packages in a single operation.

It is noted that terms such as top, bottom, over, under, and below may be used in this disclosure. These terms should not be construed as limiting the position or orientation of a structure or element, but should be used to provide spatial relationship between structures or elements.

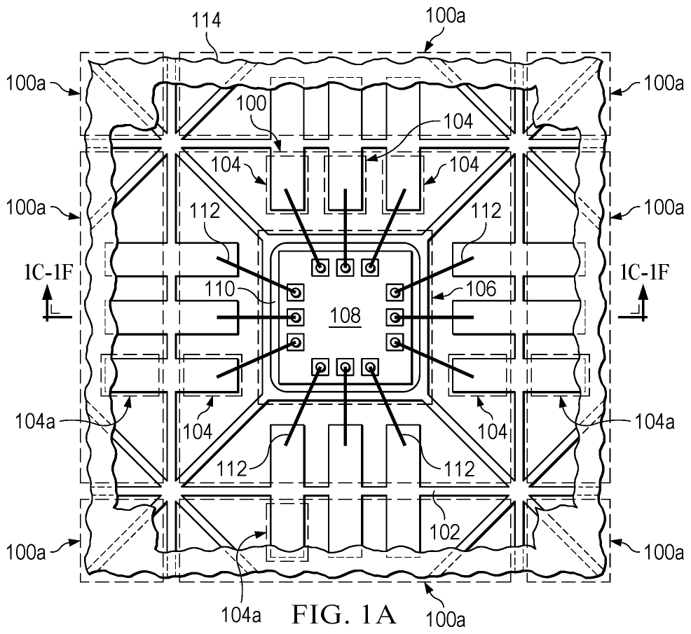

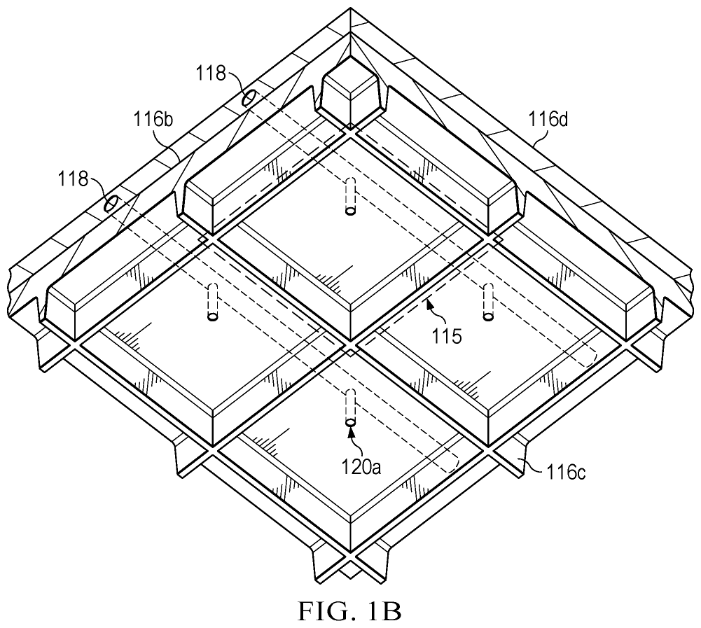

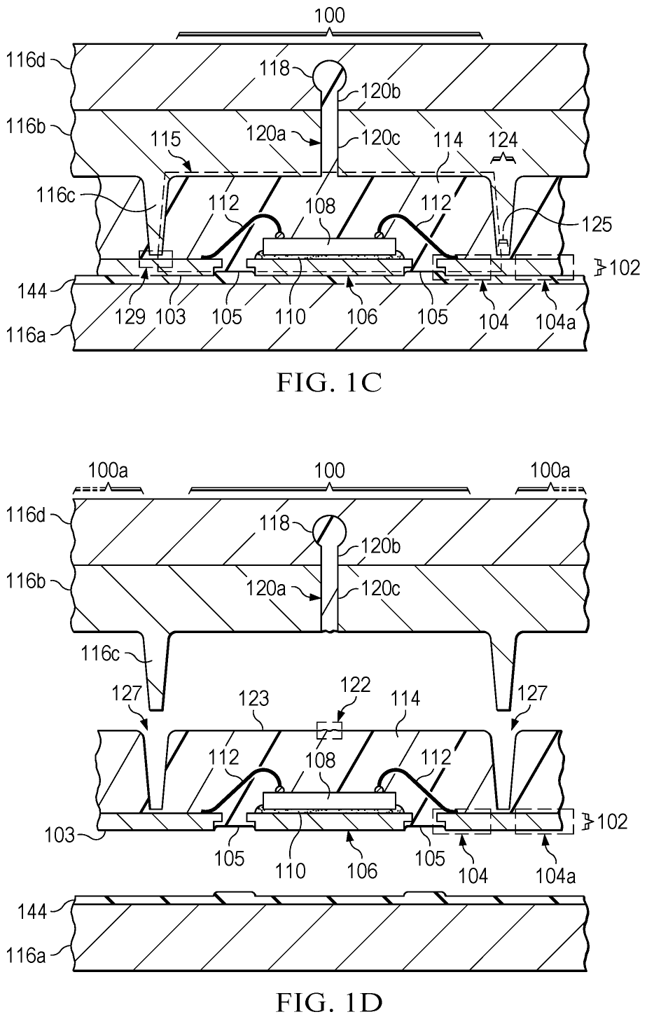

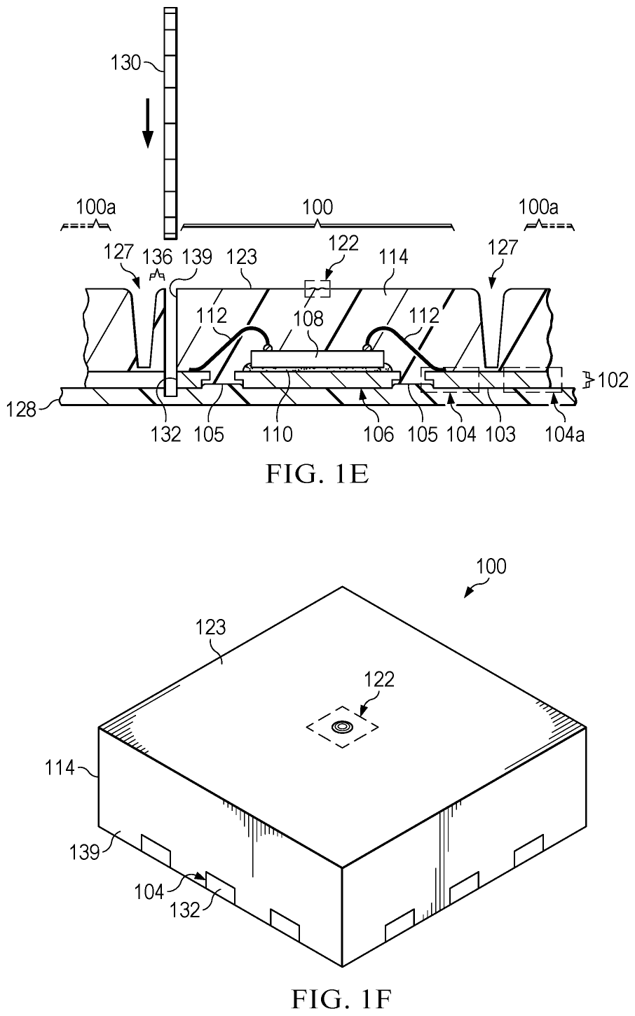

FIG. 1A is a top-down view of a semiconductor package 100 including a microelectronic component 108 attached to a lead frame 102. FIG. 1B is a perspective view of a middle mold chase 116b and a top mold chase 116d. FIG. 1C through FIG. 1E are example cross sections during the formation of the semiconductor package 100.

FIG. 1A is a top-down view of the semiconductor package 100 at the first stage of formation. Referring to FIG. 1A, the semiconductor package 100 may be formed using a lead frame 102. The lead frame 102 of this example accommodates additional semiconductor packages 100a adjacent to the semiconductor package 100.

The semiconductor package 100 includes a plurality of leads 104. Similarly, the additional semiconductor packages 100a also include a plurality of additional leads 104a. The semiconductor package 100 of this example includes a die pad 106 connected to the lead frame 102.

A microelectronic component 108 is attached to the die pad 106. The microelectronic component 108 may be manifested as an integrated circuit, a discrete component such as a power transistor, a passive component such as a transformer or a filter, a micro electromechanical system (MEMS) component, a sensor, an actuator, a microfluidic component, or an electro-optical component such as a micro-mirror array component, by way of example. The microelectronic component 108 may be attached to the die pad 106 by a die attach material 110, such as solder, an electrically conductive adhesive, an electrically insulating adhesive, or a eutectic metal alloy.

Electrical connections 112 are formed between the microelectronic component 108 and the plurality of leads 104, thus electrically coupling the microelectronic component to the plurality of leads 104. The electrical connections 112 may be implemented as wire bonds, as depicted in FIG. 1A and FIG. 1C-FIG. 1E. Alternatively, the electrical connections 112 may be implemented as ribbon bonds, clips, leads on resin coated copper, or solder bumps, by way of example.

Referring to FIG. 1B, a perspective view is shown of a portion of the middle mold chase 116b and the top mold chase 116d. The middle mold chase 116b contains a grid of middle mold chase ridges 116c which are a part of the middle mold chase 116b, protruding from the middle mold chase 116b as an array, the middle mold chase ridges 116c forming a mold cavity 115 which surrounds each semiconductor package 100 during the mold compound formation process referred to in FIG. 1C. The top mold chase 116d contains top mold chase runners 118 which allow the mold compound 114 (referred to in FIG. 1C) to be distributed within the top mold chase 116d. The top mold chase runners 118 in the top mold chase 116d are in rows or columns over each row or column of semiconductor packages 100 of the lead frame 102. The top mold chase runners 118 distribute mold compound to each semiconductor package 100 through a mold compound injection port 120a, the mold compound injection port 120a intersecting the top mold chase runners 118 and distributing the mold compound 114 into each mold cavity 115. A first portion of the mold compound injection port 120b is in the top mold chase 116d, while a second portion of the mold compound injection port 120c is in the middle mold chase 116b (referred to in FIG. 1C). While the example middle mold chase 116b shows one mold compound injection port 120a per mold cavity 115, more than one mold compound injection port 120a per mold cavity is within the scope of the disclosure. Additionally, while mold compound injection port 120a of the example device is placed above the microelectronic component 108 of the semiconductor package 100 as referred to in FIG. 1C, the top mold chase runners 118 and mold compound injection port 120a may be configured to allow the mold compound 114 to enter the mold cavity 115 through the middle mold chase ridges 116c i.e. From the side of the mold cavity 115. It may be advantageous for the mold compound injection port 120a to be over a center point of the mold cavity 115 to minimize wire sweep of the electrical connections 112 during the injection of the mold compound 114 into the mold cavity 115. (referred to in FIG. 1C). The mold compound 114 is in a liquid state as it is injected into the mold cavity 115 through the mold compound injection port 120a. Wire sweep is a phenomenon where the electrical connections 112 may be deformed during the formation of the mold compound 114.

Referring to FIG. 1C, a cross section of the semiconductor package 100 is shown during the mold compound 114 formation. In FIG. 1C, the lead frame 102 is placed between a bottom mold chase 116a and the middle mold chase 116b, with the top mold chase 116d on the middle mold chase 116b. In this example, a compressible mold relief film 144 is located between the bottom mold chase 116a and the bottom surface 103 of the plurality of leads 104. The compressible mold relief film 144 compresses between the bottom mold chase 116a and the plurality of leads 104. After the injection of the mold compound 114 into the mold cavity 115, the mold compound 114 may be flush with the bottom surface 103 of the plurality of leads 104 (not particularly shown) or may be recessed from the bottom surface 103 of the plurality of leads 104 such that the plurality of leads 104 extend below the mold compound bottom surface 105 as shown in FIG. 1C. Middle mold chase ridges 116c form the mold cavity 115. The top mold chase runners 118 provide a path for mold compound 114 to fill each the mold cavity 115 via the mold compound injection port 120a. The mold compound 114 encapsulates the plurality of leads 104, the die pad 106, the die attach material 110, the microelectronic component 108 and the electrical connection 112 between the microelectronic component 108 and the plurality of leads 104. The middle mold chase ridges 116c may have a chamfer with a middle mold chase ridge top width 124, and a middle mold chase ridge bottom width 125. The middle mold chase ridges 116c may be in contact with the plurality of leads 104, or may have a middle mold chase ridge to lead space 129. The mold compound 114 in this example is formed between the middle mold chase 116b and the compressible mold relief film 144 on the bottom mold chase 116a. The mold compound 114 is electrically insulating. The mold compound 114 may include epoxy, by way of example. The mold compound 114 may include filler particles, such as silicon dioxide particles or aluminum oxide particles, to adjust the mechanical properties of the mold compound 114.

Referring to FIG. 1D, a cross section is shown after the removal of the middle mold chase 116b and the bottom mold chase 116a. The removal of the middle mold chase 116b leaves a mold compound depression 127 resulting from the middle mold chase ridges 116c of the mold cavity 115. During the removal of the middle mold chase 116b, a sprue (not specifically shown) in the mold compound injection port 120a breaks away from the mold compound 114 of the semiconductor package 100. The breaking of the sprue from the semiconductor package 100 results in a gate cull mark 122 on the top surface 123 of the semiconductor package 100. While the gate cull mark 122 of the semiconductor package 100 is on the top surface 123, other locations of the gate cull mark 122 are within the scope of the disclosure, the location of the gate cull mark 122 being dependent of the location of the mold compound injection port 120a. The gate cull mark 122 may be circular in shape. Other shapes of the gate cull mark 122 are within the scope of the disclosure

FIG. 1E is a cross section of the semiconductor package 100 of FIG. 1D at a subsequent stage of formation during a singulation sawing process. Referring to FIG. 1E, the semiconductor package 100 and the additional semiconductor packages 100a are mounted onto a saw tape ring 128, which may also be referred to as a saw film. The semiconductor package 100 is singulated from the additional semiconductor packages 100a by a singulation sawing process using a singulation saw blade 130. The sawing process may be between the edge of the microelectronic component 108 and the mold compound depression 127.

In the example semiconductor package 100, a saw blade to mold compound depression space 136 defines a space between the mold compound depression 127 and a path for the saw blade 130 such that the semiconductor package 100 when singulated has a mold compound sidewall 139 which is vertical with respect to the top surface 123 of the mold compound 114. The mold compound sidewall 139 which is vertical results in a semiconductor package 100 after singulation with a perimeter of the mold compound 114 around the top surface 123 which is equal to the perimeter of the mold compound 114 around the bottom surface 103.

The saw blade to mold compound depression space 136 may vary based on the size of microelectronic component 108 to be packaged, and allows the middle mold chase 116b to be used in a semiconductor package 100 formation process for microelectronic components 108 of multiple different sizes. The singulation sawing process cuts through and separates the plurality of leads 104 of the semiconductor package 100 and the plurality of additional leads 104a of the additional semiconductor packages 100a, as well as the mold compound 114 between the semiconductor package 100 and the additional semiconductor packages 100a. The semiconductor package 100 and the additional semiconductor packages 100a are subsequently removed from the saw tape ring 128. The singulation sawing process produces exposed side faces 132 of the plurality of leads 104 which are free of striations, striations being typical of a semiconductor package 100 formed by shearing, instead of sawing the plurality of leads 104 from the plurality of additional leads 104a as shown in FIG. 1E

FIG. 1F is a perspective view of the semiconductor package 100 after singulation. The semiconductor package 100 after singulation may have a gate cull mark 122 and mold compound sidewalls 139. The gate cull mark 122 may be on the exterior of the semiconductor package 100 on the top surface 123 of the mold compound 114. Other features visible on the semiconductor package 100 after singulation include the plurality of leads 104 and exposed side faces 132 of the plurality of leads 104.

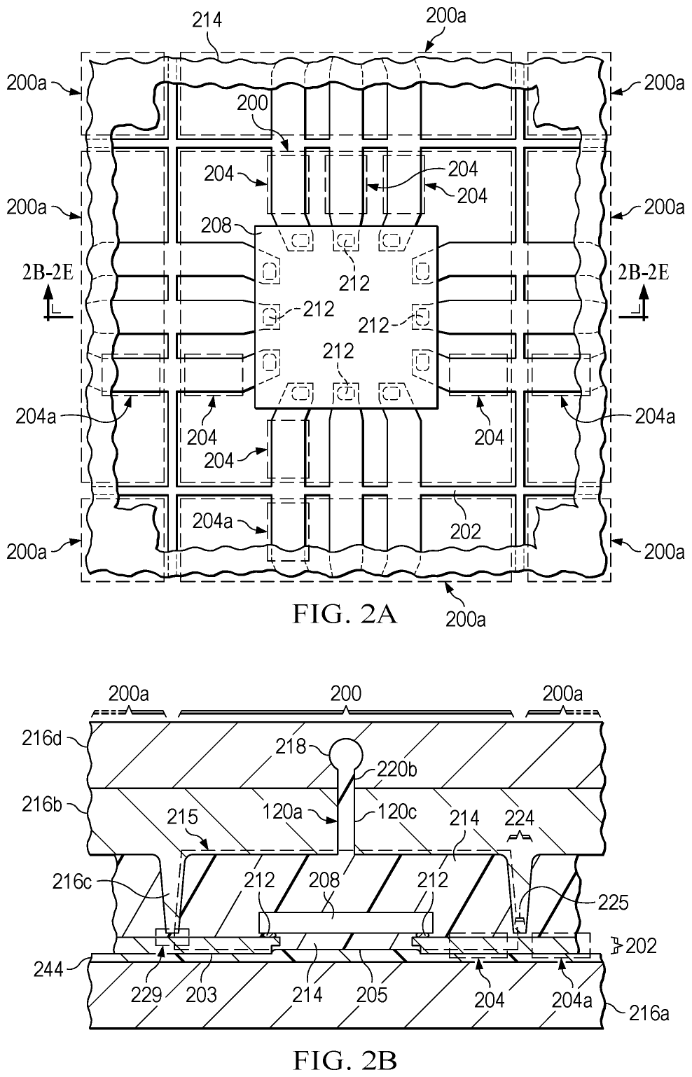

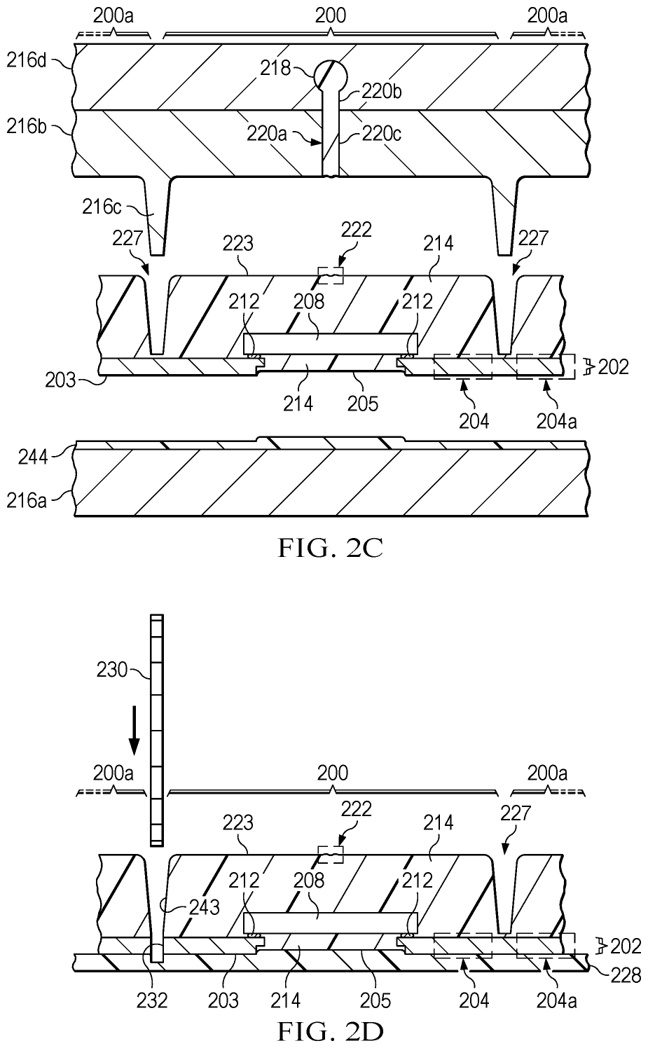

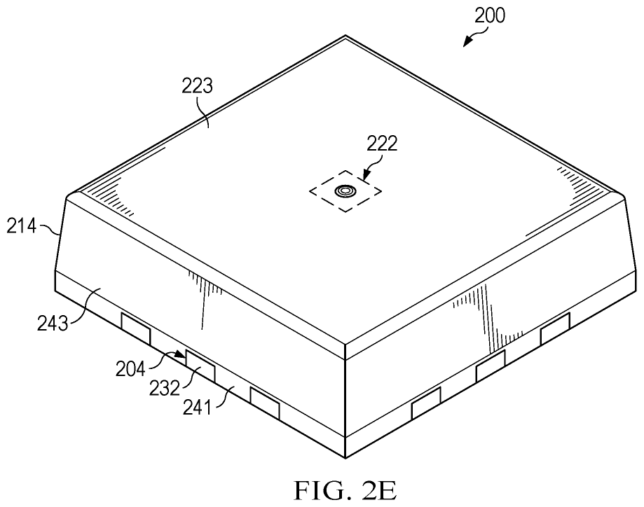

FIG. 2A is a top-down view of the semiconductor package 200 at the first stage of formation. Referring to FIG. 2A, the semiconductor package 200 may be formed using a lead frame 202. The lead frame 202 of this example may accommodates additional semiconductor packages 200a adjacent to the semiconductor package 200. The semiconductor package 200 includes a plurality of leads 204. Similarly, the additional semiconductor packages 200a also include a plurality of additional leads 204a.

A microelectronic component 208 is attached to the plurality of leads 204 through electrical connections 212, i.e. Solder balls in the example semiconductor package 200, thus electrically coupling the microelectronic component 208 to the plurality of leads 204. Other method of electrical connection between the plurality of leads 204 and the microelectronic component 208 are within the scope of the disclosure. The microelectronic component 208 may be manifested as an integrated circuit, a discrete component such as a power transistor, a passive component such as a transformer or a filter, a MEMS component, a sensor, an actuator, a microfluidic component, or an electro-optical component such as a micro-mirror array component, by way of example.

Referring to FIG. 2B, a cross section of a semiconductor package 200 shown in FIG. 2A at the point in the packaging process when the mold compound 214 is formed. In FIG. 2B, the microelectronic component 208 attached to the plurality of leads 204 is placed between a bottom mold chase 216a and the middle mold chase 216b. A top mold chase 216d is on the middle mold chase 216b. In this example, a compressible mold relief film 244 is located between the bottom mold chase 216a and the bottom surfaces 203 of the plurality of leads 204. The compressible mold relief film 244 compresses between the bottom mold chase 216a and the plurality of leads 204. After the injection of the mold compound 214 into the mold cavity 215, the mold compound 214 may be flush with the bottom surface 203 of the plurality of leads 204 (not particularly shown) or may be recessed from the bottom surface 203 of the plurality of leads 204 such that the plurality of leads 204 extend below the mold compound bottom surface 205 as shown in FIG. 2B. Middle mold chase ridges 216c which are part of the middle mold chase 216b and extend from the middle mold chase 216b to form the mold cavity 215 which surrounds the semiconductor package 200. The top mold chase runners 218 distributes the mold compound 214 to each semiconductor package 200 through a mold compound injection port 220a, the mold compound injection port 220a intersecting the top mold chase runners 218 and distributing the mold compound 214 into each mold cavity 215. A first portion of the mold compound injection port 220b is in the top mold chase 216d, while a second portion of the mold compound injection port 220c is in the middle mold chase 216b. The top mold chase runners 218 in the top mold chase 216d are in rows or columns over each row or column of microelectronic components 208 on the lead frame 202. The mold compound 214 encapsulates the plurality of leads 204, the microelectronic component 208 and the electrical connection 212 between the microelectronic component 208 and the plurality of leads 204. The middle mold chase ridges 216c may have a chamfer with a middle mold chase ridge top width 224, and a middle mold chase ridge bottom width 225. The middle mold chase ridge 216c may be in contact with the plurality of leads 204, or may have a middle mold chase ridge to lead space 229. The mold compound 214 is electrically insulating. The mold compound 214 may include epoxy, by way of example. The mold compound 214 may include filler particles, such as silicon dioxide particles or aluminum oxide particles, to adjust the mechanical properties of the mold compound 214.

Referring to FIG. 2C, a cross section is shown after the removal of the middle mold chase 216b and the bottom mold chase 216a. The removal of the middle mold chase 216b leaves a mold compound depression 227 resulting from middle mold chase ridges 216c. During the removal of the middle mold chase 216b, a sprue (not specifically shown) in the mold compound injection port 220a breaks away from the mold compound 214 of the semiconductor package 200. The breaking of the sprue from the semiconductor package 200 results in a gate cull mark 222 on the top surface 223 of the semiconductor package 100. The gate cull mark 222 may be circular in shape. While the gate cull mark 222 of the example semiconductor package 200 is on the top surface 223, other locations of the gate cull mark 222 are within the scope of the disclosure, the location of the gate cull mark 222 being dependent of the location of the mold compound injection port 220a.

FIG. 2D is a cross section of the semiconductor package 200 of FIG. 2C at a subsequent stage of formation during a singulation sawing process. FIG. 2D shows an alternative singulation sawing process compared to the process referred to in FIG. 1E. In FIG. 2D, the semiconductor package 200 and the additional semiconductor packages 200a are mounted onto a saw tape ring 228, which may also be referred to as a saw film. The semiconductor package 200 is singulated from the additional semiconductor packages 200a by a singulation sawing process using a singulation saw blade 230. In FIG. 2D, the singulation saw blade 230 is over the mold compound depression 227. Sawing through the mold compound depression 227 results in a tapered mold compound sidewall 243 above the plurality of leads 204, and a vertical mold compound sidewall 241 referred to in FIG. 2E between the plurality of leads 204. It may be advantageous for the sawing process to be centered on the mold compound depression 227 to minimize the sawing passes necessary to singulate the semiconductor package 200 from additional semiconductor packages 200a of the lead frame 202. A sawing process within the mold compound depression 227 may result in a semiconductor package 200 after singulation with the tapered mold compound sidewall 243 such that the perimeter of the mold compound 214 around the top surface 223 is less than the perimeter of the mold compound 214 around the bottom surface 203.

The singulation sawing process cuts through and separates the plurality of leads 204 of the semiconductor package 200 from the plurality of additional leads 204a of the additional semiconductor packages 200a, as well as the mold compound 214 between the semiconductor package 200 and the additional semiconductor packages 200a. The semiconductor package 200 and the additional semiconductor packages 200a are subsequently removed from the saw tape ring 228. The singulation sawing process produces exposed side faces 232 of the plurality of leads 204 which are free of striations, striations being typical of a semiconductor package 200 formed by shearing, instead of sawing the plurality of leads 204 from plurality of additional leads 204a as shown in FIG. 2D

FIG. 2E is a perspective view of the semiconductor package 200 referred to in FIG. 2D after singulation. The semiconductor package 200 after singulation may have a gate cull mark 222 and tapered mold compound sidewalls 243 above the plurality of leads 204, and vertical mold compound sidewalls 241 between the plurality of leads 204. The gate cull mark 222 may be on the exterior of the semiconductor package 200 on the top surface 223 of the mold compound 214 ash shown in FIG. 1E, or may be on the tapered mold compound sidewall 243 (not specifically shown). Other features visible on the semiconductor package 200 after singulation include the plurality of leads 204 and exposed side faces 232 of the plurality of leads 204, the exposed side faces being free of striations. Alternatively, the semiconductor package 200 can be singulated using the sawing process previously described above and shown in FIG. 1E. Similarly, the semiconductor package 100 can be singulated using the sawing process described above and shown in FIG. 2D.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A semiconductor package, comprising:
a plurality of leads around a perimeter of the semiconductor package;
a microelectronic component electrically coupled to the plurality of leads;
a mold compound contacting portions of the plurality of leads and the microelectronic component, the mold compound being electrically insulating, the mold compound having a top surface, a bottom surface, and a mold compound sidewall; and
a gate cull mark on an exterior surface of the mold compound.

2. The semiconductor package of claim 1, wherein the gate cull mark is on the top surface of the mold compound.

3. The semiconductor package of claim 1, wherein the mold compound sidewall is vertical.

4. The semiconductor package of claim 1, wherein the mold compound sidewall is tapered.

5. The semiconductor package of claim 1, wherein the microelectronic component of the semiconductor package has wire bond electrical coupling to the plurality of leads.

6. The semiconductor package of claim 1, wherein the microelectronic component of the semiconductor package has solder ball electrical coupling to the plurality of leads.

7. The semiconductor package of claim 1, wherein an exposed side face of the plurality of leads, is free of striations.

8. A method of forming a semiconductor package, comprising:
electrically coupling a microelectronic component to a plurality of leads of the semiconductor package extending to a perimeter of the semiconductor package;
forming a mold compound on the plurality of leads and the microelectronic component, the mold compound having a top surface and bottom surface wherein:
a top mold chase and a middle mold chase under the top mold chase are over the microelectronic component and the plurality of leads, the top mold chase containing top mold chase runners;
a mold compound injection port extends through the middle mold chase and into the top mold chase and intersects the top mold chase runners, wherein the mold compound is distributed to the microelectronic component and the plurality of leads through the mold compound injection port; and
a bottom mold chase is under the microelectronic component and plurality of leads;
removing the top mold chase, the middle mold chase and the bottom mold chase, the mold compound injection port forming a gate cull mark on the mold compound of the semiconductor package, and
singulating the semiconductor package through the plurality of leads.

9. The method of claim 8, wherein the semiconductor package is singulated between a mold compound depression and the microelectronic component of the semiconductor package.

10. The method of claim 8, wherein the semiconductor package is singulated along a mold compound depression between the semiconductor package and an adjacent semiconductor package.

11. The method of claim 8, wherein the middle mold chase contains middle mold chase ridges, the middle mold chase ridges forming a single mold cavity surrounding each microelectronic component and the plurality of leads of the semiconductor package.

12. The method of claim 8, comprising forming the gate cull mark on the top surface of the mold compound.

13. The method of claim 8, comprising forming the gate cull mark on a mold compound depression of the mold compound.

14. The method of claim 8, comprising forming the mold compound wherein the mold compound injection port is over a center point of a mold cavity.

15. The method of claim 8, wherein the mold compound contains filler particles, the filler particles being of silicon dioxide, aluminum oxide, or similar material.

16. The method of claim 8, wherein the microelectronic component of the semiconductor package has wire bond electrical coupling to the plurality of leads.

17. The method of claim 8, wherein the microelectronic component of the semiconductor package has solder ball electrical coupling to the plurality of leads.

18. The method of claim 8, wherein the mold compound is formed on a second plurality of leads and a second microelectronic component of a second semiconductor package, wherein the top mold chase and the middle mold chase have a second mold compound injection port, wherein the mold compound is distributed to the second semiconductor package through the second mold compound injection port.

19. The method of claim 8, comprising forming an exposed side face of the plurality of leads which is free of striations.

20. A method of forming a semiconductor packages, comprising:
electrically coupling a plurality of microelectronic components to corresponding pluralities of leads extending to corresponding perimeters of the semiconductor packages;
forming a mold compound on the plurality of microelectronic components and the corresponding pluralities of leads, the mold compound having a top surface and a bottom surface, wherein:
a top mold chase and a middle mold chase under the top mold chase are over the top surface of the mold compound, the middle mold chase containing middle mold chase ridges, the middle mold chase ridges forming a single mold cavity surrounding each of the plurality of microelectronic components and the corresponding pluralities of leads, the top mold chase containing top mold chase runners;
a plurality of mold compound injection ports extend through the middle mold chase and into the top mold chase and intersect with the top mold chase runners, wherein there is a mold compound injection port located over each of the semiconductor packages, wherein the mold compound is distributed to each microelectronic component and corresponding plurality of leads through a corresponding mold compound injection port; and
a bottom mold chase is under the plurality of microelectronic components and pluralities of leads;
removing the top mold chase, the middle mold chase and the bottom mold chase, the mold compound injection port located over each of the semiconductor packages forming a gate cull mark on the mold compound of each of the semiconductor packages, and
singulating the semiconductor packages by sawing through the pluralities of leads.
